(19) United States
(12) Patent Application Publication
(10) Pub. No.: US 2015/0380359 A1
(43) Pub. Date: Dec. 31, 2015

(54) SEMICONDUCTOR PACKAGE INCLUDING MARKING LAYER

(71) Applicant: SAMSUNG ELECTRONICS CO., LTD., Suwon-si (KR)

(72) Inventor: Jae-gil LIM, Asan-si (KR)

(73) Assignee: SAMSUNG ELECTRONICS CO., LTD., Suwon-si (KR)

(21) Appl. No.: 14/699,642

(22) Filed: Apr. 29, 2015

(30) Foreign Application Priority Data
Jun. 26, 2014 (KR) 10-2014-0079118

(51) Int. Cl. H01L 23/544; H01L 25/065; H01L 23/538; H01L 23/498; H01L 23/29; H01L 23/31

(52) U.S. Cl. CPC H01L 23/544; H01L 23/293; H01L 23/3114; H01L 23/5386; H01L 23/49838; H01L 25/0655; H01L 2223/5442; H01L 2223/54406; H01L 2223/54433

(57) ABSTRACT

A semiconductor package includes at least one semiconductor chip, an encapsulation layer encapsulating the at least one semiconductor chip, a marking layer formed on the encapsulation layer, and a product information mark formed in the marking layer.

### CROSS-REFERENCE TO RELATED APPLICATION

This application claims priority from Korean Patent Application No. 10-2014-0079118, filed on Jun. 26, 2014, in the Korean Intellectual Property Office, the disclosure of which is incorporated herein in its entirety by reference.

### BACKGROUND

1. Field

Apparatuses consistent with exemplary embodiments relate to a semiconductor package, and more particularly, to a semiconductor package including a product information mark.

2. Discussion of the Related Art

A product information mark which displays product information may be displayed on a surface of a semiconductor package. As the semiconductor package becomes smaller in thickness, it is needed to form the product information mark without damaging the semiconductor chip. Also, the product information mark needs to have good visibility to help a user easily identify the product information.

### SUMMARY

According to an aspect of an exemplary embodiment, there is provided a semiconductor package including an encapsulation layer which encapsulates at least one semiconductor chip, a marking layer which is formed on the encapsulation layer, and a product information mark which is formed in the marking layer.

The encapsulation layer may include a resin layer, and the marking layer comprises a photosensitive layer.

The marking layer may be formed on an entire surface of the encapsulation layer.

The marking layer may be formed on a portion of the surface of the encapsulation layer.

The marking layer may be formed on a portion of the surface of the encapsulation layer and have a polygonal, circular, or oval shape.

A marking depth of the product information mark may correspond to an internal portion of the marking layer.

The product information mark may comprise a discoloration layer which is a discolored portion of the marking layer.

The semiconductor package may further include a marking protection layer formed on the marking layer.

According to another aspect, there is provided a semiconductor package including at least one semiconductor chip which is mounted on a wiring substrate, an encapsulation layer which encapsulates the at least one semiconductor chip mounted on the wiring substrate, a marking layer which is formed on the encapsulation layer, a product information mark which is formed in the marking layer, and an external connection terminal which is formed on a surface of the wiring substrate.

The semiconductor package may further include internal connection wires which connect the wiring substrate and the at least one semiconductor chip, and the encapsulation layer may encapsulate the internal connection wires and the at least one semiconductor chip mounted on the wiring substrate.

The at least one semiconductor chip may include two or more semiconductor chips vertically separate from each other and may be mounted on the wiring substrate.

The at least one semiconductor chip may be vertically laminated on the wiring substrate.

The encapsulation layer may include a resin layer, the marking layer may include a photosensitive layer, and a marking depth of the product information mark may correspond to an internal portion of the marking layer.

The marking layer may be formed on an entire surface of the encapsulation layer or a portion of the entire surface of the encapsulation layer.

The product information mark may comprise a discoloration layer which is a discolored portion of the marking layer.

According to another aspect, there is provided a semiconductor package including at least one semiconductor chip which is mounted on a wiring substrate, an encapsulation layer which encapsulates an upper surface, a lower surface, and at least one side of the writing substrate, and the at least one semiconductor chip mounted on the wiring substrate, a marking layer which is formed on a surface of the encapsulation layer, a product information mark which is formed in the marking layer, and an external connection terminal which is formed on a surface of the wiring substrate.

The semiconductor package may further include internal connection wires which connect the wiring substrate and the at least one semiconductor chip, and the encapsulation layer may encapsulate the internal connection wires on the wiring substrate.

The encapsulation layer may include a resin layer, the marking layer may include a photosensitive layer, and a marking depth of the product information mark may correspond to an internal portion of the marking layer.

The marking layer may be formed on an entire surface or a portion of the entire surface of the encapsulation layer, and the product information mark may be a discoloration layer which is a discolored portion of the marking layer.

The semiconductor package may further include a marking protection layer formed on a surface of the marking layer.

### BRIEF DESCRIPTION OF THE DRAWINGS

The above and/or other aspects will become more apparent by describing certain exemplary embodiments with reference to the accompanying drawings, in which:

FIGS. 1 and 2 are cross-sectional views showing a method of marking for a semiconductor package, according to an exemplary embodiment;

FIGS. 3 and 4 are cross-sectional views showing a method of marking for a semiconductor package, according to an exemplary embodiment;

FIGS. 5A through 5C are plan views showing a method of forming a marking layer according to exemplary embodiments;

FIG. 6 is a cross-sectional view of a semiconductor package according to an exemplary embodiment;

FIG. 7 is a plan view of a marking layer and a product information mark according to an exemplary embodiment;

FIG. 8 is a diagram of a surface profile of a marking layer according to an exemplary embodiment;

FIG. 9 is a cross-sectional view of a comparative example of a semiconductor package for comparison with the semiconductor package of FIG. 6;

FIG. 10 is a plan view of an encapsulation layer and a product information mark of FIG. 9;

FIG. 11 is a diagram of a surface profile of an encapsulation layer of FIG. 10;

FIG. 12 is a cross-sectional view of a product information mark of a semiconductor package, according to an exemplary embodiment;

FIG. 13 is a cross-sectional view for explaining the product information mark of the semiconductor package of the comparative example of FIG. 9;

FIG. 14 is a cross-sectional view of a semiconductor package according to an exemplary embodiment;

FIG. 15 is a cross-sectional view of a semiconductor package according to an exemplary embodiment;

FIG. 16 is a cross-sectional view of a semiconductor package according to an exemplary embodiment;

FIG. 17 is a cross-sectional view of a semiconductor package according to an exemplary embodiment;

FIG. 18 is a cross-sectional view of a semiconductor package according to an exemplary embodiment;

FIG. 19 is a schematic diagram of a structure of a package module including semiconductor packages according to an exemplary embodiment;

FIG. 20 is a schematic diagram of a structure of a card including semiconductor packages according to an exemplary embodiment; and

FIG. 21 is a schematic diagram of a structure of an electronic system including a semiconductor package according to an exemplary embodiment.

### DETAILED DESCRIPTION

Certain exemplary embodiments will now be described more fully with reference to the accompanying drawings. The disclosure may, however, be embodied in many different forms and should not be construed as being limited to the exemplary embodiments set forth herein; rather, these exemplary embodiments are provided so that this disclosure will be thorough and complete, and will fully convey the concept of the disclosure to those skilled in the art. In the drawings, the thicknesses of layers and regions are exaggerated for clarity.

Throughout the specification, it will be understood that when an element such as a layer, region or component is referred to as being “on”, “connected to”, or “coupled to” another element, it can be directly or indirectly formed on the other layer, region, or component, or intervening layers may also be present. On the contrary, it will be understood that when an element such as a layer, region or component is referred to as being “directly on”, “directly connected to”, or “directly coupled to” another element, intervening layers may not be present. Like reference numerals may denote like elements.

While such terms as “first”, “second”, etc., may be used to describe various components, regions, layers and/or parts, such components, regions, layers and/or parts must not be limited to the above terms. The above terms are used only to distinguish one component from another. Therefore, a first member, component, region, layer, or part to be described may denote a second member, component, region, layer, or part without departing from the spirit and scope of the disclosure.

In addition, relative terms such as “on” or “above” and “under” or “below” may be used in the specification to describe a relationship between elements as shown in accompanying drawings. It will be understood that the above terms are intended to include other directions of the elements in addition to the direction illustrated in the drawings. For example, if an element, which is illustrated to be located above another element, is turned over, the element may be illustrated to be located under the other element. Therefore, the term “on” may include meanings of both “above” and “under” depending on directions of the drawings. If an element moves toward another direction (e.g., rotates about 90 degrees with regard to another direction), relative descriptions used in the specification may be understood based on the above direction.

The terms used in the specification are merely used to describe particular embodiments, and are not intended to limit the disclosure. An expression used in the singular encompasses the expression of the plural, unless it has a clearly different meaning in the context. In the specification, it is to be understood that the terms such as “including”, “having”, and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Hereinafter, the disclosure will be described more fully with reference to the accompanying drawings, in which exemplary embodiments are shown. In the drawings, for example, shapes illustrated in the drawings may vary according to manufacturing technology and/or tolerance. Therefore, the exemplary embodiments should not be construed as being limited to the embodiments set forth herein, and all differences within the scope will be construed as being included in the disclosure. The exemplary embodiments may be embodied in a certain form, and may also be embodied by incorporating one or more combinations.

A marking method which may be applied to a semiconductor package according to an exemplary embodiment may be described first.

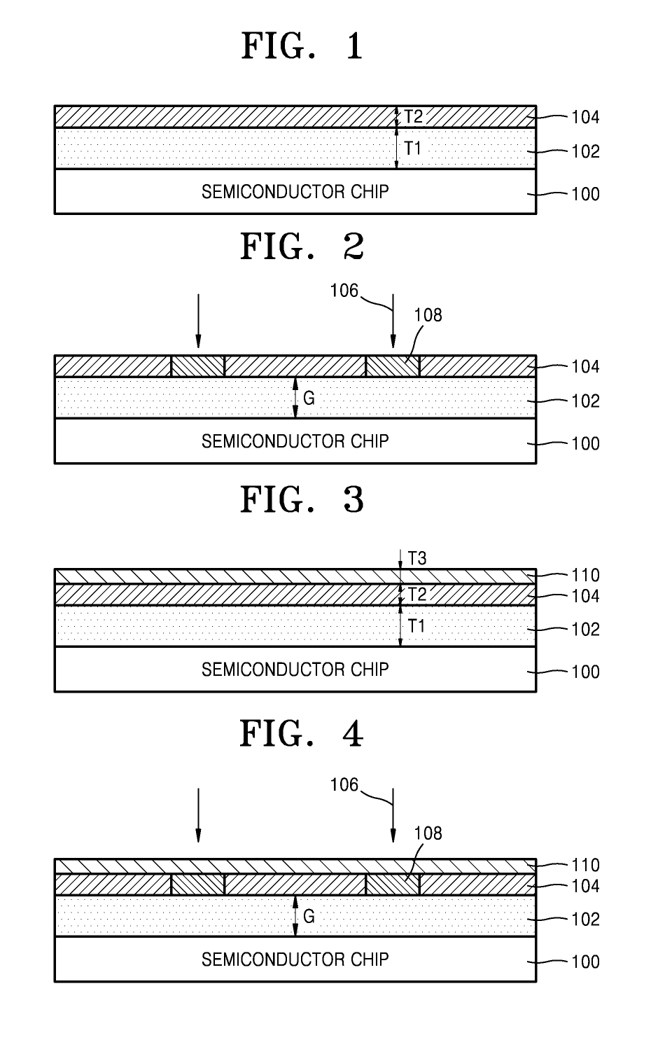

FIGS. 1 and 2 are cross-sectional views of a method of marking which may be applied to a semiconductor package, according to an exemplary embodiment.

Referring to FIG. 1, an encapsulation layer 102 is formed on a semiconductor chip 100. The encapsulation layer 102 protects the semiconductor chip 100. The encapsulation layer 102 may be a resin layer, for example, an epoxy resin layer. The encapsulation layer 102 may be a molding layer formed through a molding process. The encapsulation layer 102 may have a thickness T1, for example, a thickness ranging from about 90 μm to about 150 μm.

A marking layer 104 is formed on the encapsulation layer 102. The marking layer 104 may have a thickness smaller than that of the encapsulation layer 102. The marking layer 104 may have a thickness T2, for example, a thickness ranging from about 3 μm to about 10 μm. The marking layer 104 may be a photosensitive layer that may be discolored by light. The marking layer 104 may be formed through a spray coating method or a plasma coating method. When the encapsulation layer 102 is formed, a photoresist is spread on a surface of a release film, and then the marking layer 104 may be formed.

As described with reference to FIG. 1, the marking layer 104 may be formed on an entire surface of the encapsulation layer 102. The marking layer 104 may be formed on a portion of the entire surface of the encapsulation layer 102.

Referring to FIG. 2, a product information mark 108 is formed by irradiating a laser beam 106 onto the marking layer 104. The product information mark 108 may include semiconductor chip information, a manufacture date, a company logo, etc. The laser beam 106 may be irradiated onto the marking layer 104 at a lower level in a range from about 1 W to about 5 W. Accordingly, the product information mark 108 may be formed in the marking layer 104. The product information mark 108 may be formed without damaging the encapsulation layer 102.

The product information mark 108 may be a discoloration layer which is a discolored portion of the marking layer 104. The product information mark 108 may have visibility due to a color difference between the discoloration layer which is a discolored portion of the marking layer 104 and the marking layer 104.

According to the marking method which may be applied to a semiconductor package 100 according to an exemplary embodiment, the marking layer 104 is formed on the encapsulation layer 102, and then the product information mark 108 is formed in the marking layer 104. Therefore, according to the marking method which may be applied to a semiconductor package 100 according to an exemplary embodiment, the product information mark 108 having the visibility may be formed without damage to the encapsulation layer 102 or the semiconductor chip 100.

Since the product information mark 108 may be formed in the marking layer 104 without damage to the semiconductor chip 100 according to the marking method which may be applied to a semiconductor package 100 according to an exemplary embodiment, a distance G between an upper surface of the semiconductor chip 100 and that of the encapsulation layer 102, that is, the thickness T1 of the encapsulation layer 102, may be decreased. Accordingly, a semiconductor chip according to an exemplary embodiment may be smaller in thickness.

FIGS. 3 and 4 are cross-sectional views of a marking method which may be applied to a semiconductor package, according to an exemplary embodiment. FIGS. 3 and 4 are schematic diagrams for explaining the marking method according to an exemplary embodiment.

Referring to FIGS. 3 and 4, a marking protection layer 110 is formed on the marking layer 104.

As shown in FIG. 3, the marking protection layer 110 may be formed on the marking layer 104. The marking protection layer 110 may have substantially the same thickness as the marking layer 104. The marking protection layer 110 may have a thickness T3, for example, a thickness ranging from about 3 μm to about 10 μm. The marking protection layer 110 protects the marking layer 104 and may adjust an amount of laser beams irradiated onto the marking layer 104. The marking protection layer 110 may be a transparent layer, for example, a transparent resin layer.

As shown in FIG. 4, the product information mark 108 is formed by irradiating the laser beam 106 onto the marking protection layer 110. As described with reference to FIG. 2, the laser beam 106 may be irradiated onto the marking protection layer 110 at a lower level in a range from about 1 W to about 5 W. The product information mark 108 may be a discoloration layer which is a discolored portion of the marking layer 104. The product information mark 108 may have visibility due to a color difference between the discoloration layer which is a discolored portion of the marking layer 104 and the marking layer 104.

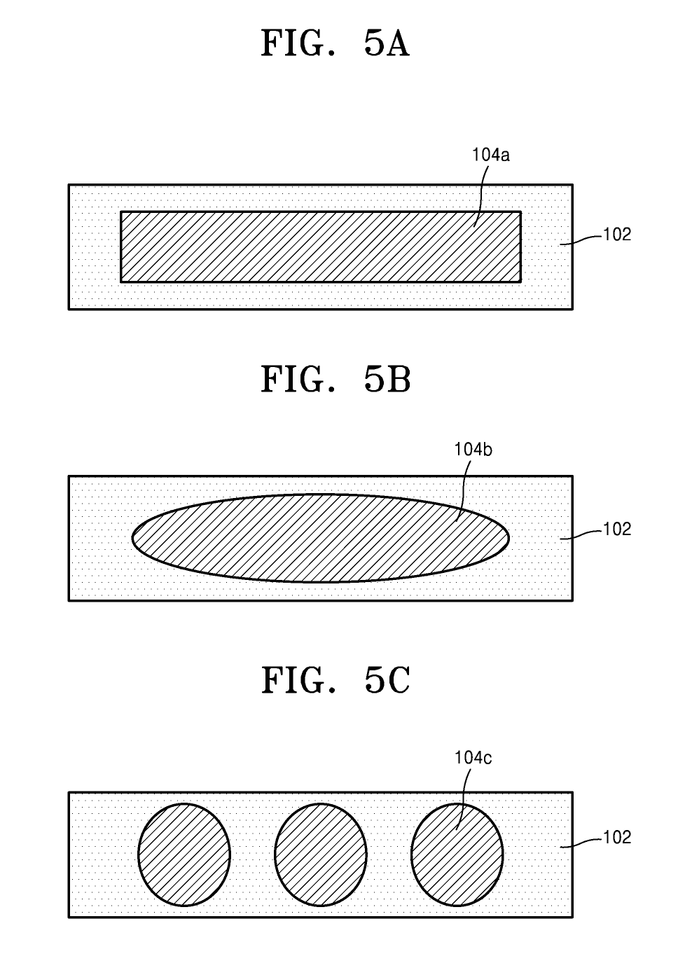

FIGS. 5A through 5C are plan views showing a method of forming the marking layer 104 according to an exemplary embodiment.

Referring to FIGS. 1 and 4, the marking layer 104 may be formed on an entire surface of the encapsulation layer 102. The marking layers 104a, 104b and 104c may be formed on portions of the entire surface of the encapsulation layer 102, as shown in FIGS. 5A through 5C. The marking layers 104a, 104b and 104c may be formed on portions of the entire surface of the encapsulation layer 102 and may have a polygonal, circular, or oval shape.

As shown in FIG. 5A, the marking layer 104a may be formed on a portion of the entire surface of the encapsulation layer 102 and may have a polygonal shape, for example, a rectangular shape. The marking layer 104b may be formed on a portion of the entire surface of the encapsulation layer 102 and may have an oval shape as shown in FIG. 5B. The marking layers 104c may be formed on portions of the entire surface of the encapsulation layer 102 and may have a circular shape as shown in FIG. 5C. However, the marking layer 104a, 104b and 104c are not limited to illustrations of FIGS. 5A through 5C and may have various shapes.

Hereinafter, a semiconductor package which is formed through the marking methods of FIGS. 1 through 4 will be described.

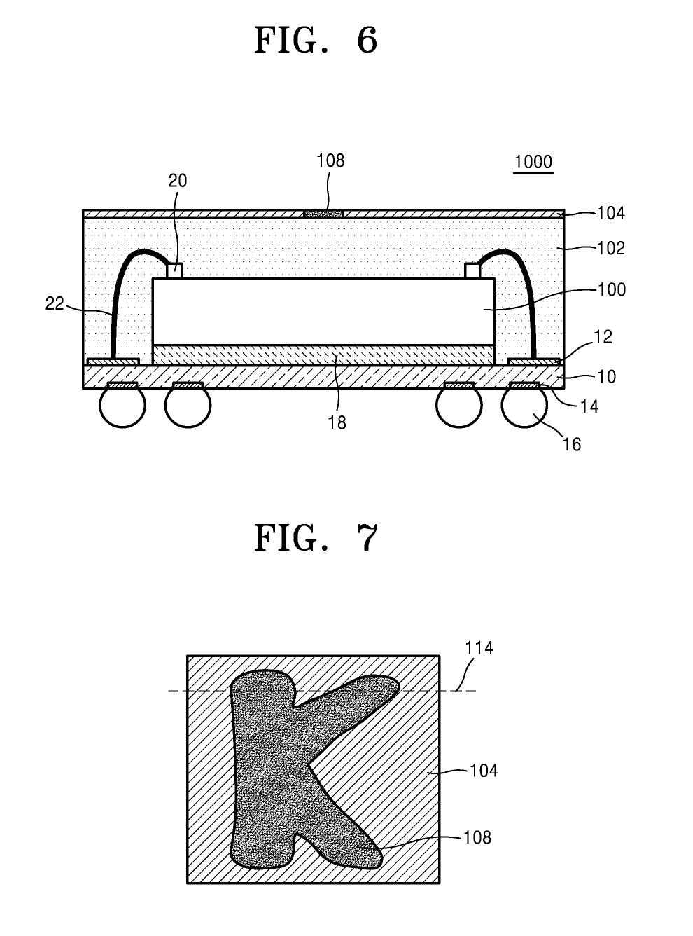

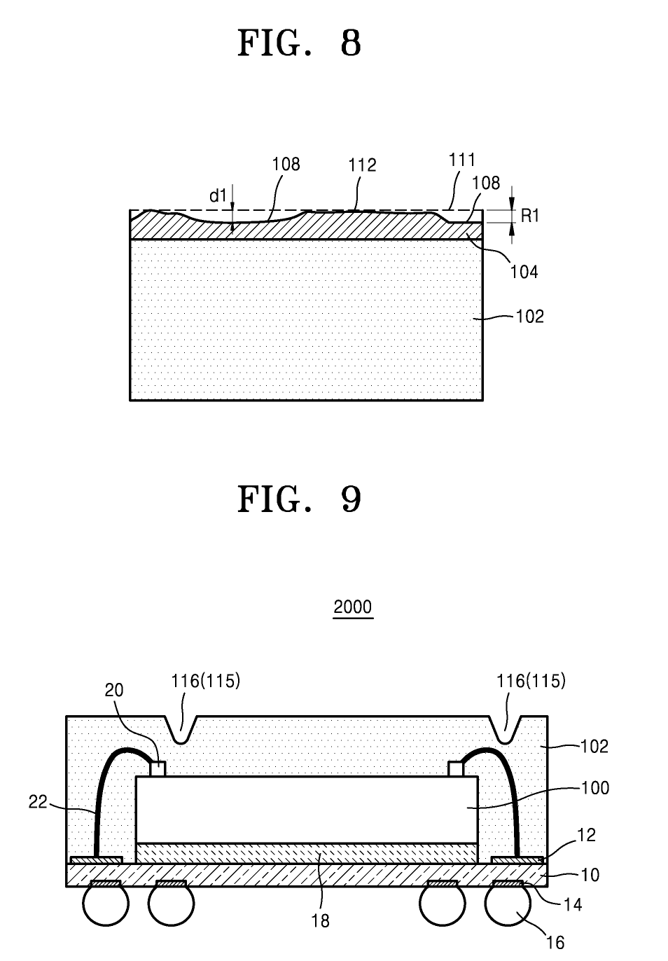

FIG. 6 is a cross-sectional view of a semiconductor package 1000 according to an exemplary embodiment, and FIG. 7 is a plan view of the marking layer 104 and the product information mark 108 of FIG. 6, according to an exemplary embodiment. FIG. 8 is a diagram of a surface profile of the marking layer 104 of FIG. 6.

In an exemplary embodiment, the semiconductor package 1000 includes at least one semiconductor chip 100 mounted on a wiring substrate 10. The semiconductor chip 100 may be mounted on the wiring substrate 10 by a bonding layer 18. A top connection pad 12 and a bottom connection pad 14 may be formed on an upper surface and a lower surface of the wiring substrate 10, respectively.

An external connection terminal 16 connected to the bottom connection pad 14 may be formed on the lower surface of the wiring substrate 10. The external connection terminal 16 may be a solder ball. A chip pad 20 may be formed on an upper surface of the semiconductor chip 100. The chip pad 20 and the top connection pad 12 may be connected by an internal connection wire 22. The internal connection wire 22 may be a bonding wire.

The encapsulation layer 102 may be formed to seal the upper surface and sides of the semiconductor chip 100 on the wiring substrate 10. The encapsulation layer 102 may cover the semiconductor chip 100 and the internal connection wire 22 on the wiring substrate 10. The marking layer 104 is formed on the encapsulation layer 102. The product information mark 108 is formed in the marking layer 104.

As shown in FIG. 7, the product information mark 108 is formed in the marking layer 104. As shown in FIG. 7, the product information mark 108 may be a discoloration layer which is a discolored portion of the marking layer 104. The product information mark 108 may have visibility due to a color difference between the discoloration layer which is a discolored portion of the marking layer 104 and the marking layer 104.

A surface profile 112 of the marking layer 104 of FIG. 6, which is formed along a line 114 in FIG. 7, will be shown in FIG. 8. A surface roughness of the marking layer 104 may be represented as R1 in FIG. 8. As shown in FIG. 8, the product information mark 108 may have a greatest marking depth d1 from a surface 111 of the marking layer 104. A marking depth of the product information mark 108 is formed in the marking layer 104 and may not damage the encapsulation layer 102.

Accordingly, as described above, the semiconductor package 1000 may have the product information mark 108 having visibility without damage to the encapsulation layer 102 and an entire thickness of the semiconductor package 1000 may be smaller by decreasing a thickness of the encapsulation layer 102.

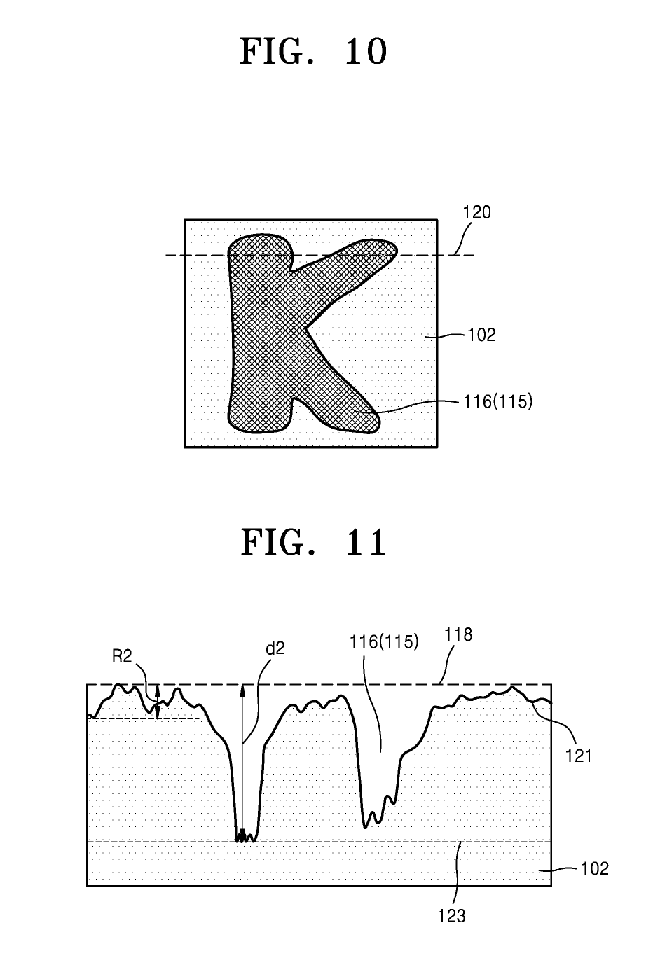

FIG. 9 is a cross-sectional view of a semiconductor package 2000 of a comparative example for comparison with the semiconductor package 1000 of FIG. 6, and FIG. 10 is a plan view of the encapsulation layer 102 and a product information mark 116 of FIG. 9. FIG. 11 is a diagram of a surface profile 121 of the encapsulation layer 102 of FIG. 10. In FIGS. 6 through 11, like reference numerals refer to like elements.

In an exemplary embodiment, when the semiconductor package 1000 and the semiconductor package 2000 of the comparative example are compared, there are no differences except for the encapsulation layer 102 and the product information mark 116. That is, similar to the semiconductor package 1000, in the semiconductor package 2000, the semiconductor chip 100 is mounted on the wiring substrate 10 by interposing the bonding layer 18 therebetween. The external connection terminal 16 which is connected to the bottom connection pad 14 is formed on the lower surface of the wiring substrate 10. The chip pad 20 is formed on the upper surface of the semiconductor chip 100. The top connection pad 12 and the chip pad 20 are connected by the internal connection wire 22.

The encapsulation layer 102 is formed to seal the upper surface and sides of the semiconductor chip 100 on the wiring substrate 10. On an upper surface of the encapsulation layer 102, the product information mark 116 is formed as etching grooves 115 which are etched by a laser beam. Since the product information mark 116 of the comparative example is formed by etching the upper surface of the encapsulation layer 102, a level of irradiation energy of the laser beam in the comparative example needs to be greater than that of the irradiation energy for forming the product information mark 108.

For example, the product information mark 116 is formed by irradiating a laser beam onto the encapsulation layer 102 at a higher level in a range from about 15 W to about 25 W. Accordingly, when the product information mark 116 is formed, the encapsulation layer 102 may be damaged, and if the damage is greater, the internal connection wire 22 may be exposed outside.

As shown in FIGS. 9 and 10, the product information mark 116 may have visibility due to a difference between the encapsulation layer 102 and the etching grooves 115. The surface profile 121 of the encapsulation layer 102 of FIG. 9, which is formed along a line 120 in FIG. 10, will be shown in FIG. 11. In FIG. 11, a surface roughness of the encapsulation layer 102 may be represented as R2. As shown in FIG. 11, the product information mark 116 has a greatest marking depth d2 from a surface 118 to a line 123 of the encapsulation layer 102. Since the marking depth d2 of the product information mark 116 is greater, the encapsulation layer 102 may be damaged.

Accordingly, when the semiconductor package 1000 of FIG. 6 and the semiconductor package 2000 of FIG. 9 are compared, the thickness of the encapsulation layer 102 and that of the semiconductor package 2000 may not be decreased because the product information mark 116 is formed by damaging the encapsulation layer 102.

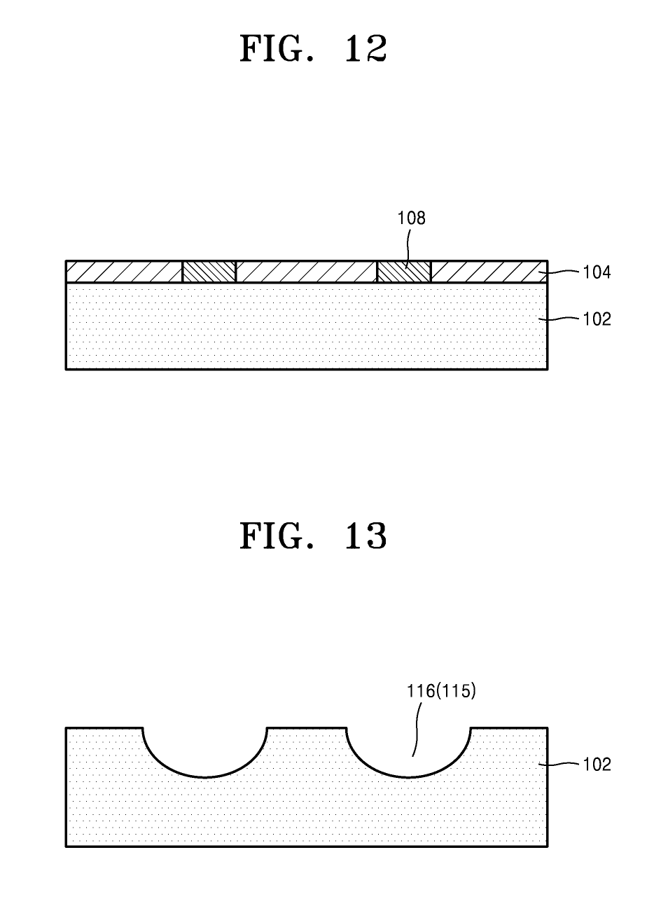

FIG. 12 is a cross-sectional view of the product information mark 108 of the semiconductor package 1000, according to the exemplary embodiment of FIG. 6, and FIG. 13 is a cross-sectional view for explaining the product information mark 1160 of the semiconductor package 2000 of the comparative example of FIG. 9.

In particular, as shown in FIG. 12, the product information mark 108 of the semiconductor package 1000 is formed in the marking layer 104. The product information mark 108 may be a discoloration layer which is a discolored portion of the marking layer 104. The product information mark 108 may have visibility due to a color difference between the discoloration layer which is a discolored portion of the marking layer 104 and the marking layer 104. The product information mark 108 of the semiconductor package 1000 is disposed in the marking layer 104 and does not damage the encapsulation layer 102.

In comparison with the above description of the product information mark 108 of the semiconductor package 1000, the product information mark 116 of the semiconductor package 2000 is formed of the etching grooves 115 formed on the encapsulation layer 102, as shown in FIG. 13. The product information mark 116 may have visibility due to a difference between the encapsulation layer 102 and the etching grooves 115. Since a marking depth of the product information mark 116 is greater, the encapsulation layer 102 may be damaged.

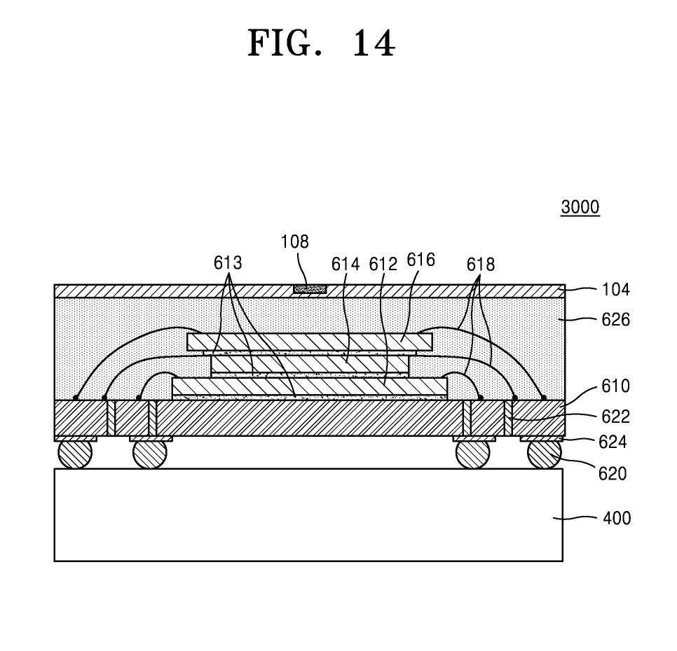

FIG. 14 is a cross-sectional view of a semiconductor package 3000 according to an exemplary embodiment.

In an exemplary embodiment, the marking layer 104 and the product information mark 108 described above are included in the semiconductor package 3000. The semiconductor package 3000 may be a stack package in which semiconductor chips 612, 614 and 616 are stacked.

In the semiconductor package 3000, different types of the semiconductor chips 612, 614 and 616 are stacked by using bonding layers 613 on a wiring substrate 610, for example, a printed circuit board (PCB) substrate. The semiconductor chips 612, 614 and 616 may have different sizes and performances and may be memory circuit chips or logic circuit chips. The semiconductor chips 612, 614 and 616 are electrically connected to the wiring substrate 610 by using an internal connection wire 618.

Accordingly, the semiconductor chips 612, 614 and 616 may be connected to the wiring substrate 610 by using the internal connection wire 618. The semiconductor chips 612, 614 and 616 and the internal connection wire 618 on the wiring substrate 610 are sealed by an encapsulation layer 626. The encapsulation layer 626 may correspond to the encapsulation layer 102 of FIG. 6. The marking layer 104 is formed on the encapsulation layer 626, and the product information mark 108 is formed in the marking layer 104.

Through vias 622 are formed in the wiring substrate 610 and connected to external connection terminals 620 via connection pads 624. The external connection terminals 620 may be disposed on a mother substrate 400. According to an exemplary embodiment, the external connection terminals 620 are not disposed and connected to the mother substrate 400.

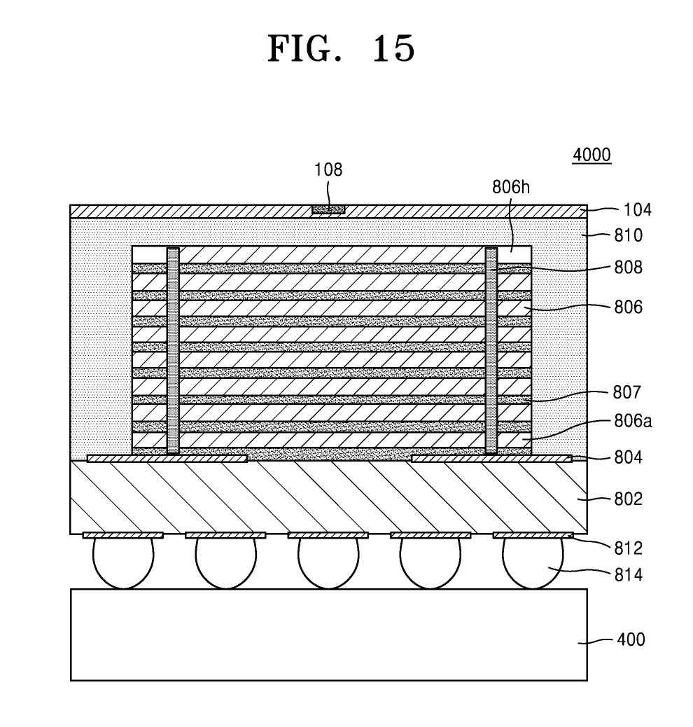

FIG. 15 is a cross-sectional view of a semiconductor package 4000 according to an exemplary embodiment.

The marking layer 104 and the product information mark 108 described above are included in an exemplary embodiment of the semiconductor package 4000. The semiconductor package 4000 may be a stack package in which semiconductor chips 806 including 806a and 806h are stacked on a wiring substrate 802, for example, a PCB substrate. First and second connection pads 804 and 812 may be respectively formed on upper and lower surfaces of the wiring substrate 802.

The semiconductor chips 806a and 806h are stacked on the wiring substrate 802 by using bonding layers 807 and are connected to the wiring substrate 802 by through vias 808. The semiconductor chips 806a and 806h may have the same size and performance. The semiconductor chips 806a and 806h may be a memory circuit chip or a logic circuit chip. The semiconductor chips 806a and 806h are encapsulated by an encapsulation layer 810 on the wiring substrate 802. The encapsulation layer 810 may correspond to the encapsulation layer 102 of FIG. 6. The marking layer 104 is formed on the encapsulation layer 810, and the product information mark 108 is formed in the marking layer 104.

In FIG. 15, two of the semiconductor chips 806 have reference numerals 806a and 806h for convenience of explanation. The through vias 808 may be connected to the first connection pad 804. An external connection terminal 814 formed on a lower surface of the wiring substrate 802 may be electrically connected to the mother substrate 400. According to an exemplary embodiment, the external connection terminal 814 may not be disposed on and connected to the mother substrate 400.

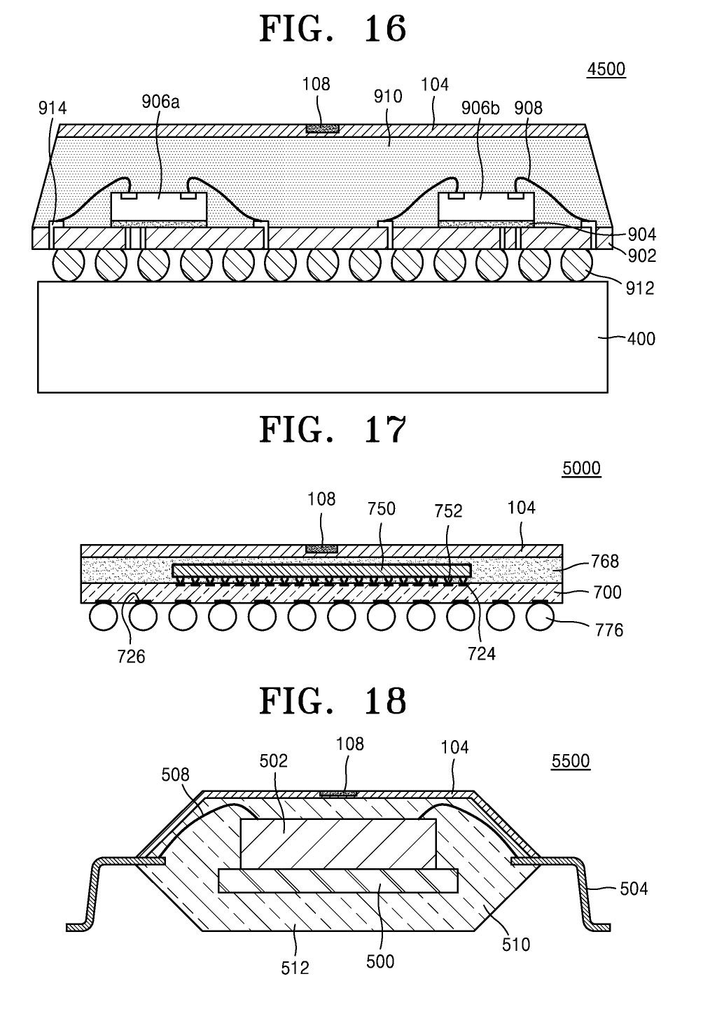

FIG. 16 is a cross-sectional view of a semiconductor package 4500 according to an exemplary embodiment.

In an exemplary embodiment, the marking layer 104 and the product information mark 108 described above are included in the semiconductor package 4500. The semiconductor package 4500 may be a horizontal stack package in which first and second semiconductor chips 906a and 906b are horizontally stacked on a wiring substrate 902, for example, a PCB substrate.

Through vias 904 may be formed on the wiring substrate 902. The first semiconductor chip 906a is mounted on the wiring substrate 902. The first semiconductor chip 906a and the second semiconductor chip 906b are horizontally separate from each other and mounted on the wiring substrate 902. The first and second semiconductor chips 906a and 906b are mounted on the wiring substrate 902, but exemplary embodiments are not limited thereto. The semiconductor chips 906a and 906b may be connected to the through vias 904 by internal connection wires 908.

The semiconductor chips 906a and 906b may have the same performance or size. The semiconductor chips 906a and 906b may be a memory circuit chip or a logic circuit chip. The semiconductor chips 906a and 906b may be encapsulated by an encapsulation layer 910 on the wiring substrate 902. The encapsulation layer 910 may correspond to the encapsulation layer 102 of FIG. 6.

The marking layer 104 is formed on the encapsulation layer 910, and the product information mark 108 is formed in the marking layer 104.

FIG. 17 is a cross-sectional view of a semiconductor package 5000 according to an exemplary embodiment.

In an exemplary embodiment, the marking layer 104 and the product information mark 108 described above are included in the semiconductor package 5000. A first connection pad 724 is formed on a wiring substrate 700, for example, an upper surface of a PCB substrate. A semiconductor chip 750 connected to the first connection pad 724 is mounted on the wiring substrate 700. The semiconductor chip 750 may be a flip chip. A connection terminal 752 of the semiconductor chip 750 is connected to the first connection pad 724. The first connection pad 724 may be a solder ball.

In the semiconductor package 5000, an encapsulation layer 768 which encapsulates the connection terminal 752 and the semiconductor chip 750 is formed on an upper surface of the wiring substrate 700. The encapsulation layer 768 may correspond to the encapsulation layer 102 of FIG. 6. The marking layer 104 is formed on the encapsulation layer 768, and the product information mark 108 is formed in the marking layer 104.

A second connection pad 726 is formed on a lower surface of the wiring substrate 700. An external connection terminal 776 which may be connected to an external device may be formed on the second connection pad 726. The external connection terminal 776 may be a solder ball.

FIG. 18 is a cross-sectional view of a semiconductor package 5500 according to an exemplary embodiment.

In an exemplary embodiment, the marking layer 104 and the product information mark 108 described above are included in the semiconductor package 5500. A semiconductor chip 502 is formed on a wiring substrate 500, for example, a lead frame. The semiconductor chip 502 may be connected to a lead 504 by using an internal connection wire 508. The lead 504 may be an external connection terminal that may be connected to an external device.

An encapsulation layer 510, which encapsulates internal connection wires 508 and upper and lower surfaces of the wiring substrate 500 including the semiconductor chip 502 formed thereon, is formed in the semiconductor package 5500. The encapsulation layer 510 may correspond to the encapsulation layer 102 of FIG. 6. The marking layer 104 described above is formed on a portion of the encapsulation layer 510, and the product information mark 108 is formed in the marking layer 104.

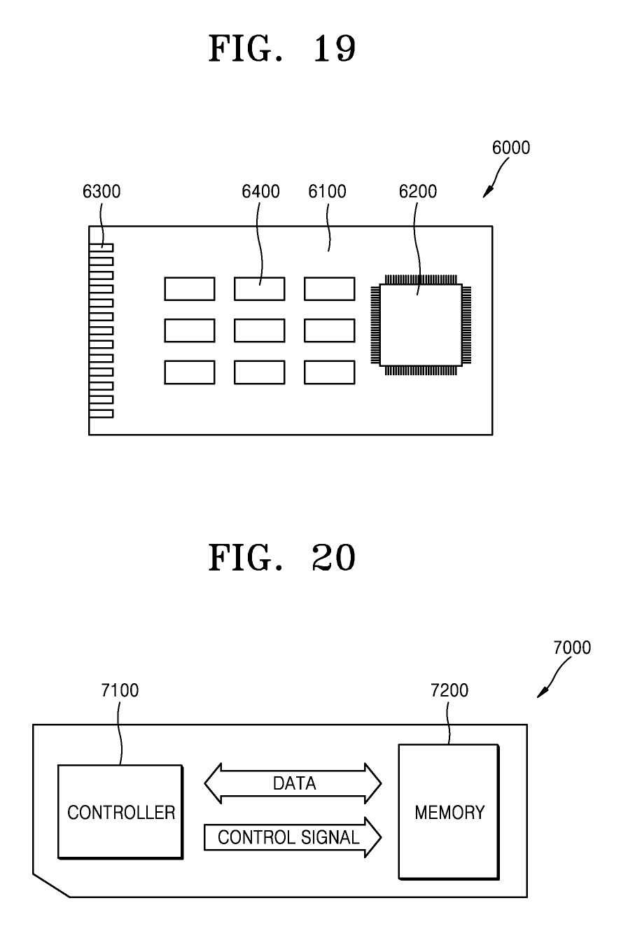

FIG. 19 is a schematic diagram of a structure of a package module 6000 using a semiconductor package 1000, 3000, 4000, 4500, 5000 and 5500 according to an exemplary embodiment.

In an exemplary embodiment, the semiconductor packages 1000, 3000, 4000, 4500, 5000 and 5500 described above may be applied to the package module 6000. When the semiconductor packages 1000, 3000, 4000, 4500, 5000 and 5500 are applied to the package module 6000, the mother substrate 400 may not be needed.

Semiconductor packages 6400 may be attached to a module substrate 6100 of the package module 6000. A control semiconductor package 6200 may be attached to a first side of the package module 6000, and an external connection terminal 6300 may be attached to a second side of the package module 6000. The semiconductor packages 1000, 3000, 4000, 4500, 5000 and 5500 described above may be used for at least one of the control semiconductor package 6200 and the semiconductor package 6400.

FIG. 20 is a schematic diagram of a structure of a card 7000 using the semiconductor packages 1000, 2000, 3000, 4000, 4500, 5000 and 5500 according to an exemplary embodiment.

In an exemplary embodiment, the semiconductor packages 1000, 3000, 4000, 4500, 5000 and 5500 described above may be applied to the card 7000. The card 7000 may include a multimedia card (MMC), a secure digital card (SD), or the like. The card 7000 includes a controller 7100 and a memory 7200. The memory 7200 may be a flash memory, a phase change random access memory (PRAM), or other types of a non-volatile memory. The controller 7100 transmits control signals to the memory 7200 and exchanges data with the memory 7200.

The semiconductor packages 1000, 3000, 4000, 4500, 5000 and 5500 described above may be used for at least one of the controller 7100 and the memory 7200 included in the card 7000.

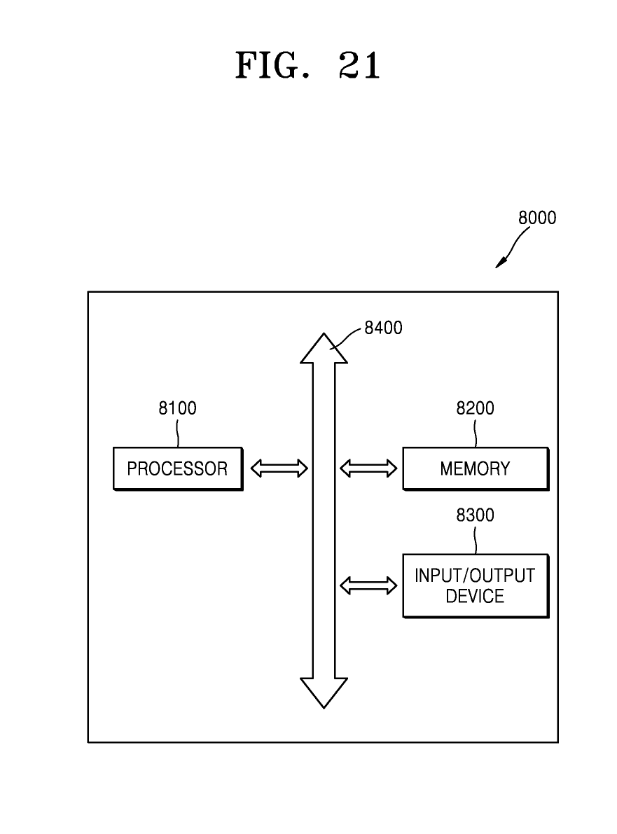

FIG. 21 is a schematic diagram of a structure of an electronic system 8000 including a semiconductor package according to an exemplary embodiment.

In an exemplary embodiment, the electronic system 8000 may be a computer, a mobile phone, a moving picture experts group (MPEG) audio layer-3 (MP3), a navigator, etc. The electronic system 8000 includes a processor 8100, a memory 8200, and an input/output device 8300. The processor 8100 exchanges control signals or data with the memory 8200 or the input/output device 8300 by using a communication channel 8400. The semiconductor packages 1000, 3000, 4000, 4500, 5000 and 5500 may be used for at least one of the processor 8100 and the memory 8200 of the electronic system 8000.

According to exemplary embodiments, a semiconductor package including a product information mark which has good visibility without damage to a semiconductor chip may be achieved.

While the exemplary embodiments have been particularly shown and described with reference to exemplary embodiments thereof, it will be understood that various changes in form and details may be made therein without departing from the spirit and scope of the following claims.

What is claimed is:

1. A semiconductor package comprising:
at least one semiconductor chip;
an encapsulation layer encapsulating the at least one semiconductor chip;
a marking layer formed on the encapsulation layer; and
a product information mark formed in the marking layer.

2. The semiconductor package of claim 1, wherein the encapsulation layer comprises a resin layer, and the marking layer comprises a photosensitive layer.

3. The semiconductor package of claim 1, wherein the marking layer is formed on an entire surface of the encapsulation layer.

4. The semiconductor package of claim 1, wherein the marking layer is formed on a portion of a surface of the encapsulation layer.

5. The semiconductor package of claim 4, wherein the marking layer has a polygonal, a circular, or an oval shape.

6. The semiconductor package of claim 1, wherein a marking depth of the product information mark corresponds to an internal portion of the marking layer.

7. The semiconductor package of claim 1, wherein the product information mark comprises a discolored portion of the marking layer.

8. The semiconductor package of claim 1, further comprising a marking protection layer formed on the marking layer.

9. A semiconductor package comprising:
at least one semiconductor chip mounted on a wiring substrate;
an encapsulation layer encapsulating the at least one semiconductor chip mounted on the wiring substrate;
a marking layer formed on the encapsulation layer;
a product information mark formed in the marking layer; and
an external connection terminal formed on a surface of the wiring substrate.

10. The semiconductor package of claim 9, further comprising internal connection wires which connect the wiring substrate and the at least one semiconductor chip,
wherein the encapsulation layer encapsulates the internal connection wires and the at least one semiconductor chip mounted on the wiring substrate.

11. The semiconductor package of claim 9, wherein the at least one semiconductor chip comprises two or more semiconductor chips vertically separate from each other and mounted on the wiring substrate.

12. The semiconductor package of claim 9, wherein the at least one semiconductor chip is vertically laminated on the wiring substrate.

13. The semiconductor package of claim 9, wherein the encapsulation layer comprises a resin layer,
the marking layer comprises a photosensitive layer, and
a marking depth of the product information mark corresponds to an internal portion of the marking layer.

14. The semiconductor package of claim 13, wherein the marking layer is formed on an entire surface of the encapsulation layer or a portion of a surface of the encapsulation layer.

15. The semiconductor package of claim 14, wherein the product information mark comprises a discolored portion of the marking layer.

16. A semiconductor package comprising:
at least one semiconductor chip mounted on a wiring substrate;
an encapsulation layer which encapsulates an upper surface, a lower surface, and at least one side of the writing substrate, and the at least one semiconductor chip mounted on the wiring substrate;
a marking layer formed on a surface of the encapsulation layer;
a product information mark formed in the marking layer; and
an external connection terminal formed on a surface of the wiring substrate.

17. The semiconductor package of claim 16, further comprising internal connection wires which connect the wiring substrate and the at least one semiconductor chip,
wherein the encapsulation layer encapsulates the internal connection wires on the wiring substrate.

18. The semiconductor package of claim 17, wherein the encapsulation layer comprises a resin layer,
the marking layer comprises a photosensitive layer, and
a marking depth of the product information mark corresponds to an internal portion of the marking layer.

19. The semiconductor package of claim 18, wherein the marking layer is formed on an entire surface or a portion of a surface of the encapsulation layer, and
the product information mark comprises a discolored portion of the marking layer.

20. The semiconductor package of claim 18, further comprising a marking protection layer formed on a surface of the marking layer.
